(19) United States
(12) Patent Application Publication
(10) Pub. No.: US 2024/0341081 A1
(43) Pub. Date: Oct. 10, 2024

(54) SEMICONDUCTOR DEVICE

(71) Applicant: SAMSUNG ELECTRONICS CO., LTD., Suwon-si (KR)

(72) Inventors: Hongjun LEE, Suwon-si (KR); Keunnam KIM, Suwon-si (KR); Seungmuk KIM, Suwon-si (KR); Kiseok LEE, Suwon-si (KR)

(21) Appl. No.: 18/388,295

(22) Filed: Nov. 9, 2023

(30) Foreign Application Priority Data
Apr. 4, 2023 (KR) 10-2023-0044057

(51) Int. Cl. H10B 12/00; G11C 5/06

(52) U.S. Cl. CPC H10B 12/315; G11C 5/063; H10B 12/482; H10B 12/485; H10B 12/488; H10B 12/50

(57) ABSTRACT

A semiconductor device which includes a semiconductor substrate having a cell area and a peripheral area, the peripheral area including a first area and a second area adjacent to each other, first transistors on the first area, a first wiring layer on the first transistors, a first pad on the second area and a portion of the first area, a first contact plug between the first wiring layer and the first area, a second contact plug between the first pad and the first area, a second pad on the first wiring layer, a third contact plug between the second pad and the first wiring layer, and a plurality of first capacitors on the second pad and that vertically overlap the first transistors, thus reliability and electrical characteristics of the semiconductor device may be increased.

### CROSS-REFERENCE TO RELATED APPLICATIONS

This application claims priority under 35 U.S.C. § 119 to Korean Patent Application No. 10-2023-0044057 filed on Apr. 4, 2023, in the Korean Intellectual Property Office, the disclosures of which are incorporated by reference herein in their entireties.

### BACKGROUND

### 1. Field

Embodiments of the present disclosure described herein relate to a semiconductor device.

### 2. Description of the Related Art

Semiconductor devices are widely used in the electronic industry because of their small size, multi-functionality, and/or low manufacturing cost. The semiconductor devices may be classified into semiconductor memory devices that store logic data, semiconductor logic devices that perform operation and processing on logic data, and hybrid semiconductor devices that include a memory element and a logic element.

Recently, with the high speed and low power consumption of electronic devices, semiconductor devices embedded therein also require fast operating speeds and/or low operating voltages. In order to meet these requirements, highly integrated semiconductor devices are required. However, with the high integration of semiconductor devices, reliability and electrical characteristics of the semiconductor devices may be decreased. Accordingly, studies are being conducted to improve reliability and electrical characteristics of semiconductor devices.

### SUMMARY

Embodiments are directed to a semiconductor device including a semiconductor substrate including a cell area and a peripheral area, the peripheral area including a first area and a second area adjacent to each other, first transistors on the first area, a first wiring layer on the first transistors, a first pad on the second area and a portion of the first area, a first contact plug between the first wiring layer and the first area, a second contact plug between the first pad and the first area, a second pad on the first wiring layer, a third contact plug between the second pad and the first wiring layer, and a plurality of first capacitors on the second pad vertically overlapping the first transistors.

Embodiments are directed to a semiconductor device, including a semiconductor substrate including a cell area and a peripheral area, the peripheral area including a first area and a second area adjacent to each other, first transistors on the first area, a first wiring layer on the first transistors, a first pad on the second area, a second pad on the first wiring layer and on the first area spaced apart from the first pad in a third direction perpendicular to an upper surface of the semiconductor substrate, a first contact plug configured to connect the first wiring layer and the second pad, a first capacitor on the second pad including a first lower electrode connected with the second pad, a first upper electrode on the lower electrode, and a first dielectric film between the first lower electrode and the first upper electrode, a second capacitor on the first pad including a second lower electrode connected with the first pad, a second upper electrode on the second lower electrode, and a second dielectric film between the second lower electrode and the second upper electrode.

Embodiments are directed to a semiconductor device including a semiconductor substrate including a cell area and a peripheral area around the cell area, the peripheral area including a first area and a second area, cell activation patterns on the cell area, word lines configured to cross the cell activation patterns inside the semiconductor substrate, bit lines configured to cross the word lines on the semiconductor substrate, a landing pad on the bit lines, a first capacitor on the landing pad, second transistors on the second area, a first pad electrically connected with the bit lines and on the second area, a portion of the first area, and the second transistors, first transistors on the first area, a first wiring layer on the first transistors, a second pad spaced apart from the first pad in a third direction perpendicular to an upper surface of the semiconductor substrate and on the first wiring layer, the first area, and a portion of the second area, a third contact plug configured to connect the first wiring layer and the second pad, a second capacitor on the second pad, and a third capacitor on the first pad.

### BRIEF DESCRIPTION OF THE FIGURES

Features will become apparent to those of skill in the art by describing in detail exemplary embodiments with reference to the attached drawings in which:

FIG. 1 is a plan view of a semiconductor device according to an embodiment of the present disclosure;

FIG. 2A is a plan view of a portion of a bank area of the semiconductor device according to an embodiment of the present disclosure;

FIG. 2B is a sectional view taken along line T-T′ of FIG. 2A;

FIG. 3 is a sectional view of the semiconductor device according to an embodiment of the present disclosure taken along line S-S′ of FIG. 1;

FIG. 4A is a sectional view of the semiconductor device according to an embodiment of the present disclosure taken along line R-R′ of FIG. 1;

FIG. 4B is an enlarged view of portion CU1 of FIG. 4A;

FIG. 5A is a sectional view of the semiconductor device according to another embodiment of the present disclosure taken along line R-R′ of FIG. 1;

FIG. 5B is an enlarged view of portion CU2 of FIG. 5A.

FIG. 6A is a sectional view of the semiconductor device according to another embodiment of the present disclosure taken along line R-R′ of FIG. 1;

FIG. 6B is an enlarged view of portion CU3 of FIG. 6A;

FIG. 7 is a sectional view of the semiconductor device according to another embodiment of the present disclosure taken along line R-R′ of FIG. 1; and

FIGS. 8A to 8K are sectional views of a semiconductor device showing various steps in a method of manufacturing the semiconductor device according to an embodiment of the present disclosure.

### DETAILED DESCRIPTION

Hereinafter, embodiments of the present disclosure will be described in detail with reference to the accompanying drawings.

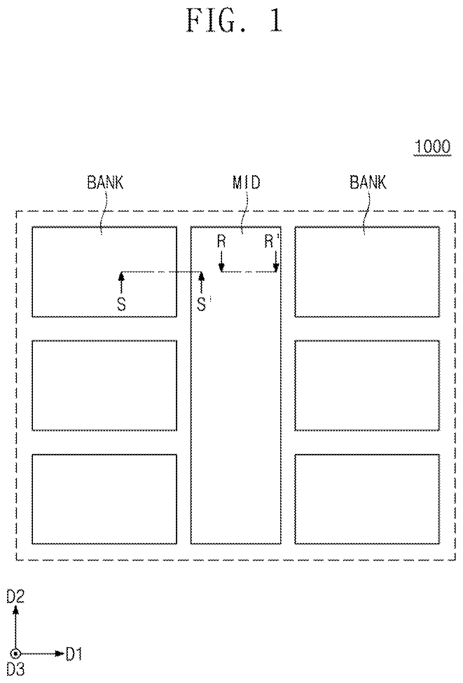

FIG. 1 is a plan view of a semiconductor device according to an embodiment of the present disclosure.

Referring to FIG. 1, the semiconductor device 1000 may include bank areas BANK and a mid-area MID between the bank areas BANK. The bank areas BANK may be spaced apart from each other in a first direction D1 with the mid-area MID therebetween. The bank areas BANK may be arranged in a second direction D2 perpendicular to the first direction D1. The mid-area MID may extend in the second direction D2. The semiconductor device 1000 may be a memory device, and the bank area BANK may include a cell circuit such as a memory integrated circuit. The mid-area MID may include various peripheral circuits required for operation of the cell circuit, and the peripheral circuits may be electrically connected to the cell circuit.

In an implementation, the mid-area MID may include sense amplifier circuits and sub-word line driver circuits. The mid-area MID may further include ground driver circuits and a power source for driving a sense amplifier.

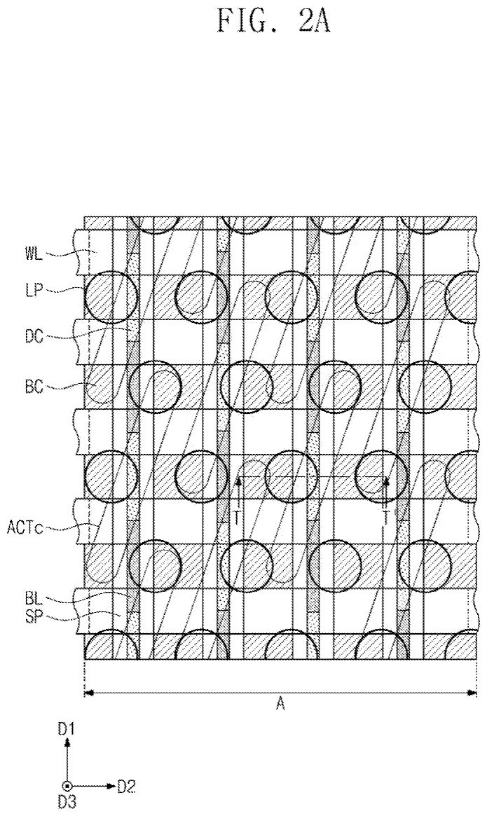

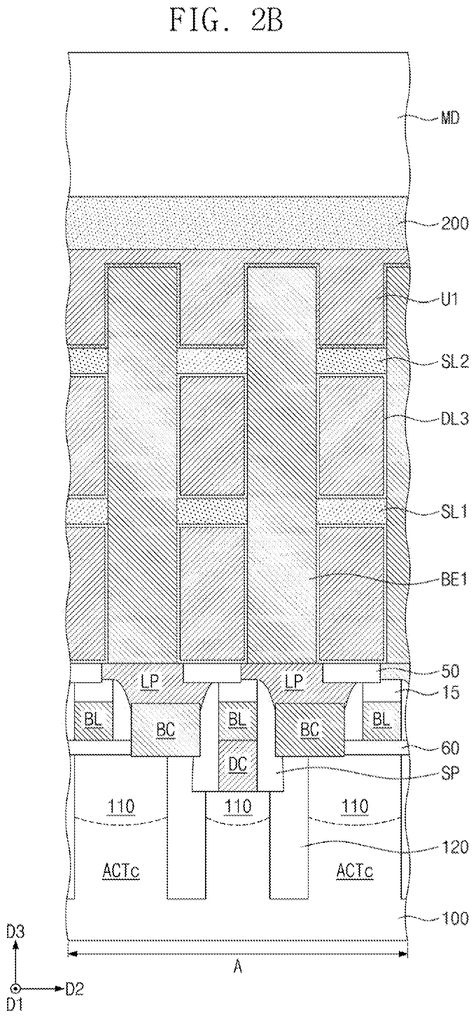

FIG. 2A is a plan view of a portion of a bank area of the semiconductor device according to an embodiment of the present disclosure. FIG. 2B is a sectional view taken along line T-T′ of FIG. 2A.

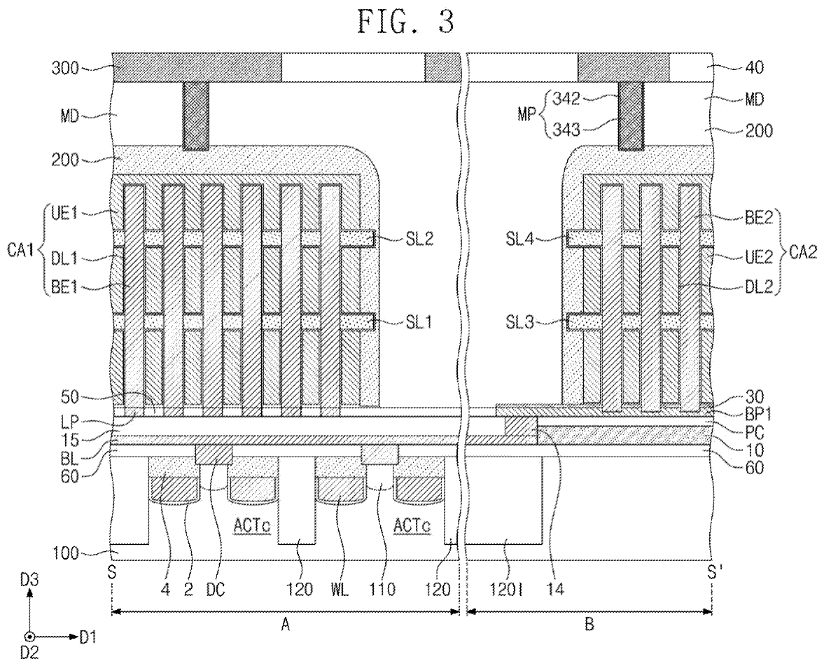

FIG. 3 is a sectional view corresponding to line S-S′ of FIG. 1. FIG. 3 is a sectional view showing a portion of the mid-area and a portion of the bank area.

Referring to FIGS. 1 and 3, the semiconductor device 1000 may include a semiconductor substrate 100 that may include a cell area A and a peripheral area B. The cell area A may be in the bank area BANK, and the peripheral area B may be in the mid-area MID.

In this specification, the first direction D1 is defined as a direction parallel to an upper surface of the semiconductor substrate 100. The second direction D2 is defined as a direction parallel to the upper surface of the semiconductor substrate 100 and perpendicular to the first direction D1. A third direction D3 is defined as a direction perpendicular to the upper surface of the semiconductor substrate 100.

Referring to FIGS. 2A, 2B, and 3, cell activation patterns ACTc may be on the cell area A of the semiconductor substrate 100.

As shown in FIG. 2A, the cell activation patterns ACTc may be spaced apart from each other in the first direction D1 and the second direction D2 when viewed in the plan view. The cell activation patterns ACTc may have a bar shape parallel to the upper surface of the semiconductor substrate 100 and extending in a diagonal direction crossing the first direction D1 and the second direction D2.

As shown in FIGS. 2B and 3, device isolation films 120 may be between the cell activation patterns ACTc on the cell area A. The device isolation films 120 may be inside the semiconductor substrate 100 to define the cell activation patterns ACTc.

A boundary separation film 120I may be between the cell area A and the peripheral area B. The boundary separation film 120I may separate the cell area A and the peripheral area B.

Word lines WL may cross the cell activation patterns ACTc and the device isolation films 120 on the cell area A. The word lines WL may be in grooves formed in the cell activation patterns ACTc and the device isolation films 120. The word lines WL may extend in the second direction D2 and may be spaced apart from each other in the first direction D1. The word lines WL may be embedded in the semiconductor substrate 100. A cell gate insulating film 2 may be interposed between the word lines WL and the semiconductor substrate 100, and word line capping patterns 4 may be on the word lines WL. Upper surfaces of the word line capping patterns 4 may be coplanar with the upper surface of the semiconductor substrate 100. The semiconductor substrate 100 may include an impurity area 110 in an upper portion thereof on the word line WL side. The impurity area 110 may correspond to a source or drain area.

A first interlayer insulating film 60 may be on the upper surface of the semiconductor substrate 100. A lower surface of the first interlayer insulating film 60 may be in contact with an upper surface of the device isolation film 120, an upper surface of the boundary separation film 120I, and the upper surface of the semiconductor substrate 100. The first interlayer insulating film 60 may include an insulating material. The insulating material may include, e.g., silicon nitride or silicon oxide. As used herein, the term “or” is not an exclusive term, e.g., “A or B” would include A, B, or A and B.

As shown in FIGS. 2A, 2B, and 3, bit lines BL crossing the word lines WL may be on the cell area A of the semiconductor substrate 100. The bit lines BL may extend in the first direction D1 and may be spaced apart from each other in the second direction D2. The bit lines BL may be spaced apart from the semiconductor substrate 100 with the first interlayer insulating film 60 enclosing a bit line contact plug DC therebetween. A side surface of each of the bit lines BL may be covered by a bit line spacer SP. Upper surfaces of the bit lines BL may be covered by bit line capping patterns 15. The bit line capping patterns 15 may include an insulating material such as a silicon nitride film. The impurity area 110 may be connected with lower electrode contact plugs BC. Landing pads LP may be on the lower electrode contact plugs BC. The landing pads LP may be insulated from each other by a second interlayer insulating film 50. The second interlayer insulating film 50 may include an insulating material. The insulating material may include, e.g., silicon nitride and silicon oxide. The lower electrode contact plugs BC may include an impurity-doped poly silicon pattern, and the landing pads LP may include a barrier metal film and metal. The barrier metal film may include, e.g., a titanium/titanium nitride film. The metal may include, e.g., tungsten. The bit line spacer SP may extend in the first direction D1 on each of the bit lines BL. The bit line contact plug DC may be interposed between the bit line BL and the impurity area 110 and may electrically connect the bit line BL and the impurity area 110.

First lower electrodes BE1 may be on the landing pads LP so as to be spaced apart from each other in the first direction D1. The first lower electrodes BE1 may include, e.g., impurity-doped poly silicon, metal nitride such as titanium nitride, or a metal film such as tungsten, aluminum, or copper. Each of the first lower electrodes BE1 may have a cylindrical shape or a hollow cylinder or cup shape. A second support pattern SL2 may support upper sidewalls of the first lower electrodes BE1, and a first support pattern SL1 may support lower sidewalls of the first lower electrodes BE1. The first and second support patterns SL and SL2 may include an insulating material such as silicon nitride, silicon oxide, or silicon oxy-nitride.

A first dielectric film DL1 may cover surfaces of the first lower electrodes BE1 and surfaces of the first and second support patterns SL1 and SL2. The first dielectric film DL1 may include, e.g., silicon oxide, silicon nitride, silicon oxy-nitride, or a high-k material. A first upper electrode UE1 may be on the first dielectric film DL1 and may fill spaces between the first lower electrodes BE1. The first upper electrode UE1 may include, e.g., an impurity-doped poly silicon film, metal nitride such as titanium nitride, or a metal film such as tungsten, aluminum, or copper. The first lower electrodes BE1, the first dielectric film DL1, and the first upper electrode UE1 may constitute a first capacitor CA1.

A plate 200 may be on the first capacitor CA1. The plate 200 may include SiGe or a metallic material. The first capacitor CA1 may be connected with a metal pattern 300 in a wiring layer 40 through a metal plug MP.

A third interlayer insulating film 10, a peripheral capping pattern PC, and a first pad BP1 to be described below may be on the peripheral area B. The third interlayer insulating film 10 may include an insulating material. The insulating material may include, e.g., silicon nitride and silicon oxide. The first pad BP1 may be electrically connected with the bit line BL through a VIA 14. In addition, a second capacitor CA2 to be described below may be on the first pad BP1. An upper surface of the landing pad LP may be at the same level as an upper surface of the first pad BP1.

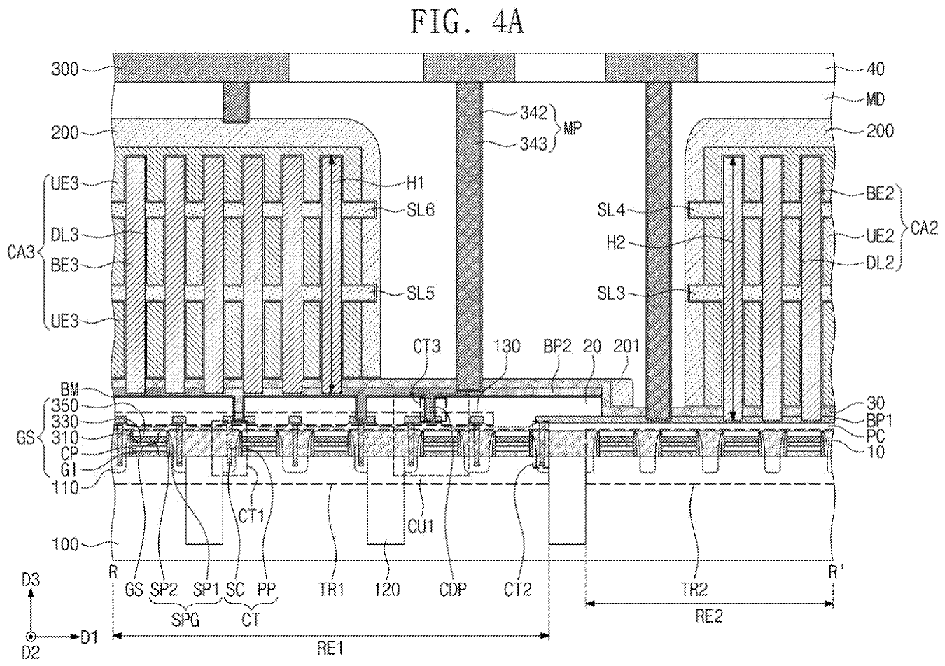

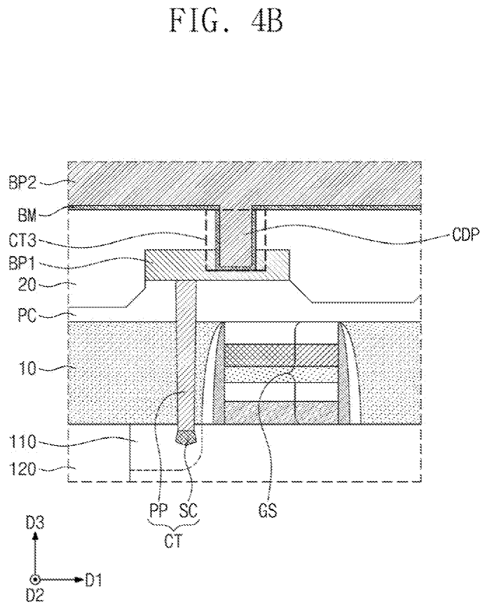

FIG. 4A is a sectional view of the semiconductor device according to an embodiment of the present disclosure taken along line S-S′ of FIG. 1. Referring to FIG. 4A, the semiconductor device 1000 according to this embodiment may include the semiconductor substrate 100, first transistors TR1, second transistors TR2, a first wiring layer 130, the first pad BP1, a second pad BP2, a first contact plug CT1, a second contact plug CT2, a third contact plug CT3, the second capacitor CA2, and a third capacitor CA3.

The semiconductor substrate 100 may include the cell area A and the peripheral area B, and the peripheral area B may include a first area RE1 and a second area RE2 adjacent to each other. The semiconductor substrate 100 may be, e.g., a silicon substrate or a silicon-on-insulator (SOI) substrate.

The device isolation film 120 may be on the semiconductor substrate 100. The device isolation film 120 may include, e.g., silicon oxide, silicon nitride, and/or silicon oxy-nitride. The first area RE1 and the second area RE2 may be spaced apart from each other by the device isolation film 120.

The first transistors TR1 may be on the first area RE1. The first transistors TR1 may include elements that perform power pumping, voltage divider, and decoupling.

Each of the first transistors TR1 may include a gate structure GS and an impurity area 110. The gate structure GS may include a gate insulating pattern GI, a conductive pattern CP, a metal containing pattern 330, and a capping pattern 350 sequentially stacked on the upper surface of the semiconductor substrate 100.

The gate insulating pattern GI may include a high-k material such as hafnium oxide (HfO), strontium titanium oxide (SrTiO), or lanthanum oxide (LaO). The conductive pattern CP may include, e.g., aluminum (Al), titanium nitride (TiN), tungsten nitride (WN), or ruthenium oxide (RuO2). The metal containing pattern 330 may include, e.g., metal such as tungsten, titanium, or tantalum. The capping pattern 350 may include, e.g., nitride.

A pair of spacer structures SPG may be on opposite side surfaces of the gate structure GS, respectively. Each of the pair of spacer structures SPG may include a first spacer SP1 and a second spacer SP2. The second spacer SP2 may be on the first spacer SP1. The second spacer SP2 may be farther away from the center of the gate structure GS than the first spacer SP1. The first spacer SP1 may include silicon nitride. The second spacer SP2 may include silicon oxide. The gate structure GS and the spacer structure SPG may extend in the second direction D2.

The semiconductor substrate 100 may include impurity areas 110. The impurity areas 110 may correspond to source/drain areas. The impurity areas 110 may be on an upper portion of the semiconductor substrate 100 so as to be spaced apart from each other with the gate structure GS therebetween.

The third interlayer insulating film 10 may be on the semiconductor substrate 100. The third interlayer insulating film 10 may cover the gate structure GS and the spacer structure SPG. The third interlayer insulating film 10 may include, e.g., silicon nitride or silicon oxide.

The peripheral capping pattern PC may cover an upper surface of the third interlayer insulating film 10. The peripheral capping pattern PC may include, e.g., silicon nitride, silicon oxide, or silicon oxy-nitride.

The fourth interlayer insulating film 20 may be on the peripheral capping pattern PC. The fourth interlayer insulating film 20 may include an insulating material. The insulating material may include, e.g., silicon nitride or silicon oxide.

The first contact plug CT1 may be on the semiconductor substrate 100. The first contact plug CT1 may include a through-plug PP and a contact pad SC. The through-plug PP may include a metallic material such as tungsten, aluminum, or the like. The contact pad SC may be a portion making direct contact with the impurity area 110. The contact pad SC may include metal such as cobalt (Co), titanium (Ti), nickel (Ni), or the like.

The first wiring layer 130 may be on the first transistors TR1. The first wiring layer 130 may be electrically connected with the first contact plug CT1.

The second transistors TR2 may be on the second area RE2. Likewise to the first transistors TR1, the second transistors TR2 may include a gate structure GS, an impurity area 110, and a spacer structure SPG. The second transistors TR2 may also be dummy transistors. In an implementation, the second transistors TR2 may not be on the second area RE2.

The first pad BP1 may be on the second transistors TR2. The first pad BP1 may be on the second area RE2 and a portion of the first area RE1. The first pad BP1 may extend to a portion of the first area RE1 in the first direction D1 beyond the second area RE2. The first pad BP1 may vertically overlap the second transistors TR2. The first pad BP1 may have a plate shape that covers the second transistors TR2. The first pad BP1 may include a metallic material such as tungsten, titanium nitride, aluminum, copper, or the like.

The second contact plug CT2 may be on a partial area of the first pad BP1 on the first area RE1. The second contact plug CT2 may be spaced apart from the second capacitor CA2, which will be described below, in the third direction D3. The second contact plug CT2 may be electrically connected with the first pad BP1 and the first wiring layer 130. A lower end of the second contact plug CT2 may be connected with the impurity area 110. An upper end of the second contact plug CT2 may be connected with the first pad BP1.

The third contact plug CT3 may be on the second pad BP2 to be described below. The third contact plug CT3 may include a conductive plug CDP and a barrier metal BM. The barrier metal BM may be on a side surface and a lower surface of the conductive plug CDP. The barrier metal BM may extend from the side surface of the conductive plug CDP and may also be on a lower surface of the second pad BP2, which will be described below, in the first direction D1. The barrier metal BM may include a titanium/titanium nitride film. Likewise to the first pad BP1, the conductive plug CDP may include a metallic material such as tungsten, titanium nitride, aluminum, copper, or the like.

The second pad BP2 may be on the first wiring layer 130 in the first direction D1. The second pad BP2 may be on the first area RE1 and a portion of the second area RE2. The second pad BP2 may extend to a portion of the second area RE2 in the first direction D1 beyond the first area RE1. The second pad BP2 may be electrically connected with the first wiring layer 130 through the third contact plug CT3. The second pad BP2 may have a plate shape that covers the first wiring layer 130. The first pad BP1 and the second pad BP2 may be spaced apart from each other in the third direction D3. The second pad BP2 may include a metallic material such as tungsten, titanium nitride, aluminum, copper, or the like.

The second capacitor CA2 may be on the first pad BP1. The second capacitor CA2 may include a second upper electrode UE2, second lower electrodes BE2, and a second dielectric film DL2. The second lower electrodes BE2 may be spaced apart from each other in the first direction D1, and portions of lower ends of the second lower electrodes BE2 may have a shape connected with the first pad BP1. The portions of the lower ends of the second lower electrodes BE2 may be disposed to penetrate portions of the first pad BP1. The second lower electrodes BE2 may include the same material as the first lower electrodes BE1. The second lower electrodes BE2 may have a pillar shape or a cylindrical shape.

A third support pattern SL3 and a fourth support pattern SL4 that extend in the first direction D1 may be provided. The fourth support pattern SL4 may support upper sidewalls of the second lower electrodes BE2, and the third support pattern SL3 may support lower sidewalls of the second lower electrodes BE2.

The second dielectric film DL2 may cover surfaces of the second lower electrodes BE2 and surfaces of the third and fourth support patterns SL3 and SL4. The second dielectric film DL2 may include the same material as the first dielectric film DL1. The second upper electrode UE2 may be on the second dielectric film DL2 and may fill spaces between the second lower electrodes BE2. The second upper electrode UE2 may include the same material as the first upper electrode UE1. The second capacitor CA2 may vertically overlap at least some of the second transistors TR2.

A third capacitor CA3 may be on the second pad BP2. The second pad BP2 and the third capacitor CA3 may vertically overlap each other. The third capacitor CA3 may be spaced apart from the third contact plug CT3 in the third direction D3. The third capacitor CA3 may include a third upper electrode UE3, third lower electrodes BE3, and a third dielectric film DL3. The third lower electrodes BE3 may be spaced apart from each other in the first direction D1. Lower ends of the third lower electrodes BE3 may have a shape connected with the second pad BP2. Portions of the lower ends of the third lower electrodes BE3 may be disposed to penetrate portions of the second pad BP2. The third lower electrodes BE3 may be formed of a conductive material. For example, the third lower electrodes BE3 may be formed of impurity-doped poly silicon, or may be formed of a metal containing film such as a titanium nitride film. The third lower electrodes BE3 may have a pillar shape or a cylindrical shape.

A fifth support pattern SL5 and a sixth support pattern SL6 that extend in the first direction D1 may be between the third lower electrodes BE3. The sixth support pattern SL6 may support upper sidewalls of the third lower electrodes BE3, and the fifth support pattern SL5 may support lower sidewalls of the third lower electrodes BE3. The fifth support pattern SL5 and the sixth support pattern SL6 may include, e.g., a material such as silicon nitride, silicon oxide, or silicon oxy-nitride.

The third dielectric film DL3 may cover surfaces of the third lower electrodes BE3 and surfaces of the fifth and sixth support patterns SL5 and SL6. The third dielectric film DL3 may include, e.g., silicon oxide, silicon nitride, silicon oxy-nitride, or a high-k material. The third upper electrode UE3 may be on the third dielectric film DL3 and may fill spaces between the third lower electrodes BE3. The third upper electrode UE3 may include, e.g., an impurity-doped poly silicon film, metal nitride such as titanium nitride, and a metal film such as tungsten, aluminum, or copper. The third capacitor CA3 may vertically overlap at least some of the first transistors TR1.

A level difference H1 between an upper surface and a lower surface of the third lower electrode BE3 in the third capacitor CA3 may differ from a level difference H2 between an upper surface and a lower surface of the second lower electrode BE2 included in the second capacitor CA2. The level of the lower surface of the third lower electrode BE3 may be higher than the level of the lower surface of the second lower electrode BE2. The second capacitor CA2 and the third capacitor CA3 may be spaced apart from each other in the first direction D1.

A fifth interlayer insulating film 30 may be on the first pad BP1 and the second pad BP2. The fifth interlayer insulating film 30 may include an insulating material. The insulating material may include, e.g., a silicon nitride or silicon oxide.

The plate 200 may be on the fifth interlayer insulating film 30. The plate 200 may have a shape that covers the first capacitor CA1. The plate 200 may include SiGe or a metallic material. A residual plate 201 may be on the fifth interlayer insulating film 30. The residual plate 201 may be on the second area RE2. The residual plate 201 may include the same material as the material constituting the plate 200.

The wiring layer 40 may be on the third capacitor CA3. The metal pattern 300 may be included in the wiring layer 40.

Metal plugs MP may be connected to the first pad BP1 and the second pad BP2. Each of the metal plugs MP may include a diffusion barrier pattern 342 and a metal pillar 343 on the diffusion barrier pattern 342. The diffusion barrier pattern 342 may include, e.g., a metal nitride (e.g., TiN, TSN, TaN, or the like). The metal pillar 343 may include a metallic material such as tungsten, aluminum, or the like. Upper ends of the metal plugs MP may be connected with the metal pattern 300 included in the wiring layer 40. The metal plugs MP may be in the third direction D3 perpendicular to the upper surfaces of the first pad BP1 and the second pad BP2. A part of the metal plugs MP may be connected with the plate 200 on the third capacitor CA3.

A mold film MD may be included between the fifth interlayer insulating film 30 and the wiring layer 40. The mold film MD may include a silicon nitride film. The mold film MD may be included in a form that fills a portion between an upper surface of the fifth interlayer insulating film 30, an outside of the plate 200, and a lower surface of the metal pattern 300.

FIG. 4B is an enlarged view of portion CU1 of FIG. 4A. Repetitive descriptions identical to ones given with reference to FIG. 4A will be omitted. The third contact plug CT3 may be connected to the first pad BP1. The third contact plug CT3 may include the conductive plug CDP and the barrier metal BM. The barrier metal BM may cover the side surface and the lower surface of the conductive plug CDP. The barrier metal BM may extend from the side surface of the conductive plug CDP and may cover the lower surface portion of the second pad BP2 on the third contact plug CT3. The third contact plug CT3 and the second pad BP2 may include the same metallic material.

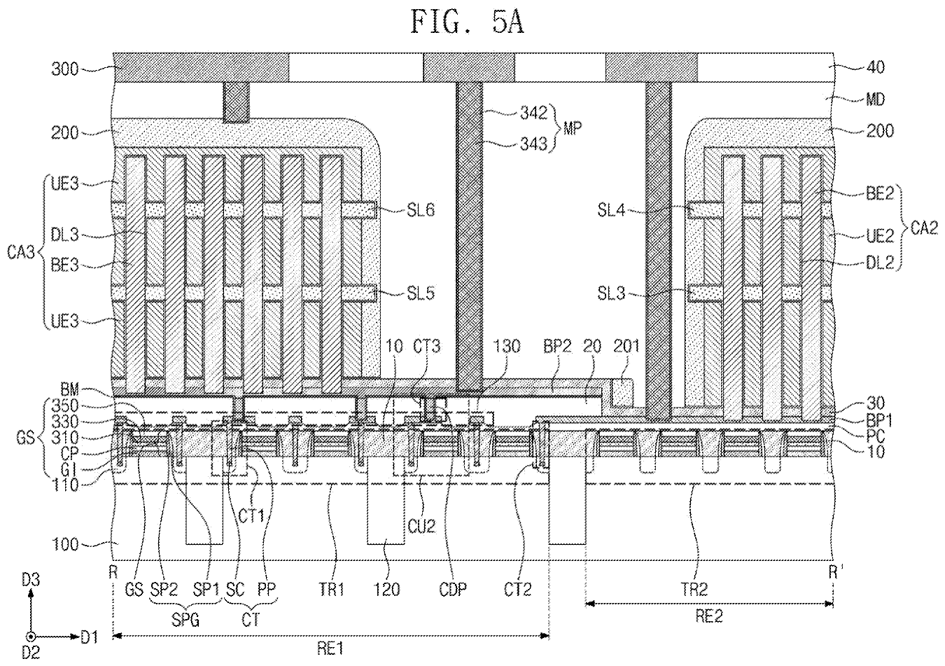

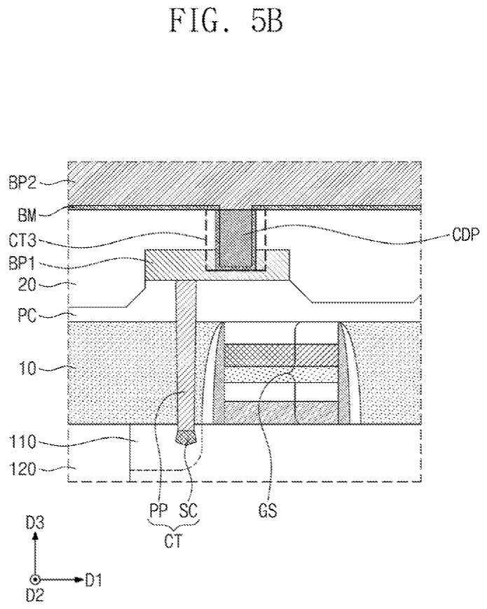

FIG. 5A is a sectional view of the semiconductor device according to another embodiment of the present disclosure taken along line S-S′ of FIG. 1. Descriptions of components identical to those shown in FIG. 4A will be omitted. Referring to FIG. 5A, the conductive plug CDP may include a material different from that of the second pad BP2. For example, while the second pad BP2 may include tungsten, the conductive plug CDP may include copper.

FIG. 5B is an enlarged view of portion CU2 of FIG. 5A. Descriptions of components identical to those shown in FIG. 4B will be omitted. As described above with reference to FIG. 5A, the conductive plug CDP may include a material different from that of the second pad BP2 and may be formed through a chemical vapor deposition process. Meanwhile, the second pad BP2 may be formed through a physical vapor deposition process. In this case, the resistance value of metal may be lowered, which may help improve electrical performance.

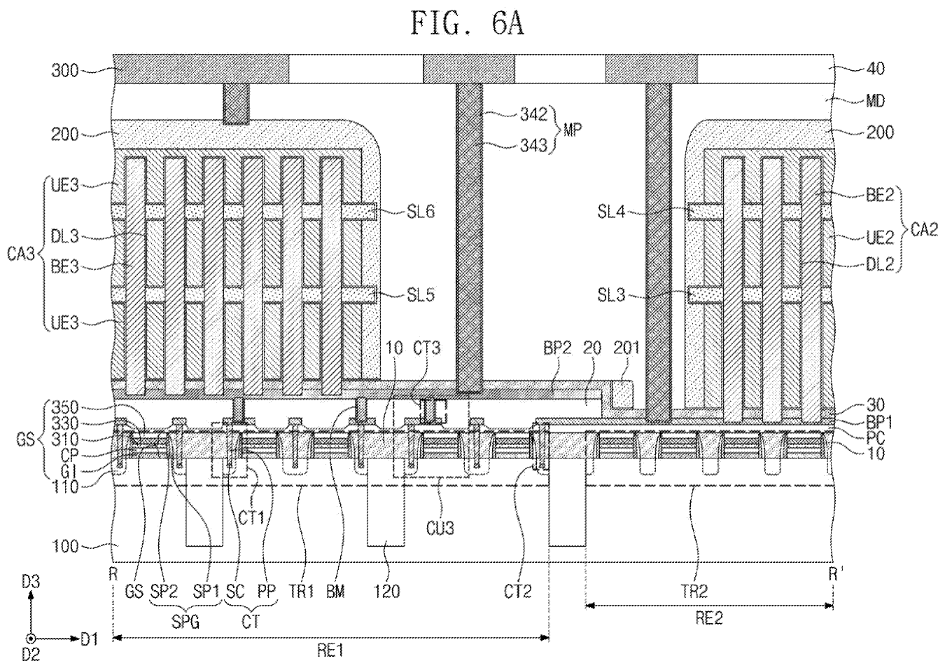

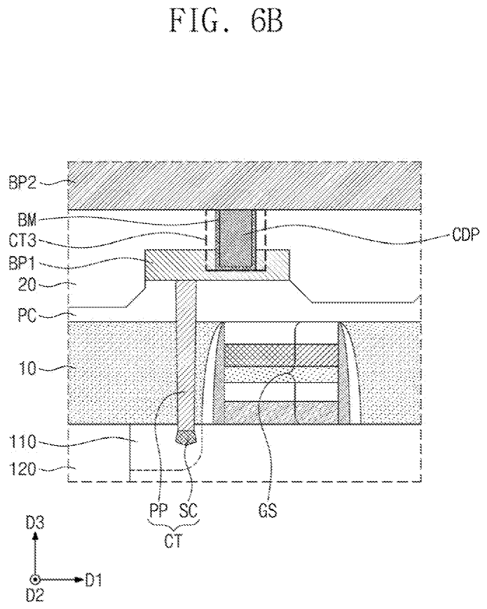

FIG. 6A is a sectional view of the semiconductor device according to another embodiment of the present disclosure taken along line S-S′ of FIG. 1. Descriptions of components identical to those shown in FIG. 5A will be omitted. The barrier metal BM may cover a side surface and a lower end surface of the third contact plug CT3. However, unlike in FIG. 5B, the barrier metal BM may not cover the lower surface of the second pad BP2.

FIG. 6B is an enlarged view of portion CU3 of FIG. 6A. Descriptions of components identical to those shown in FIG. 6A will be omitted. The barrier metal BM may be formed through a patterning process during deposition to cover only the side surface and the lower end surface of the conductive plug CDP. Accordingly, the barrier metal BM may not be formed on the lower surface of the second pad BP2.

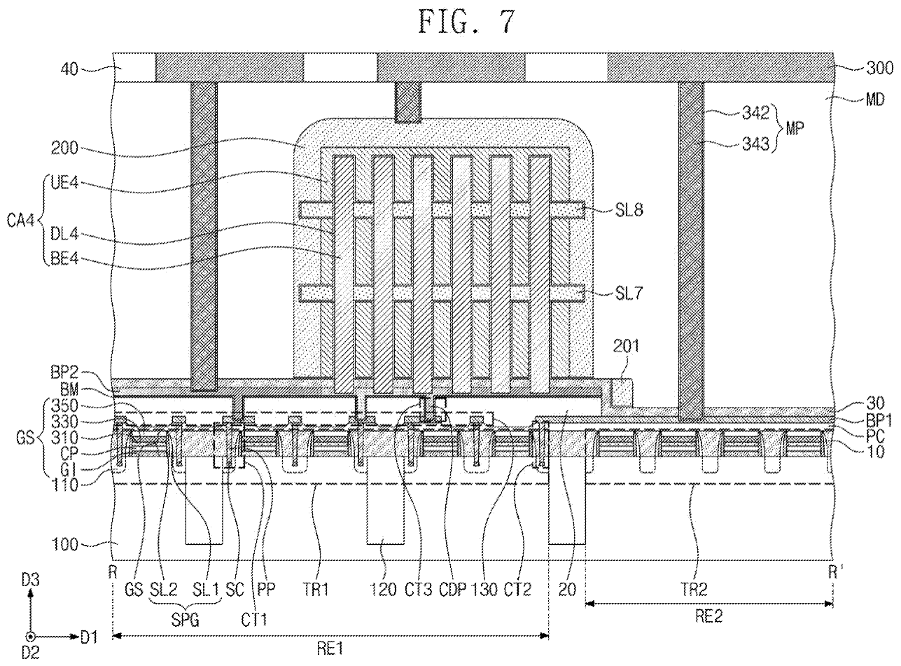

FIG. 7 is a view of the semiconductor device according to an embodiment of the present disclosure, where FIG. 7 shows another embodiment of the sectional view corresponding to line R-R′ in FIG. 1. Repetitive descriptions identical to ones given with reference to FIG. 4A will be omitted. Referring to FIG. 7, a fourth capacitor CA4 may be on the second pad BP2. In contrast, a separate capacitor may not be on the first pad BP1. The fourth capacitor CA4 may include a fourth upper electrode UE4, fourth lower electrodes BE4, and a fourth dielectric film DL4. The fourth lower electrodes BE4 may be spaced apart from each other in the first direction D1. Lower ends of the fourth lower electrodes BE4 may have a shape connected with the second pad BP2. Portions of the lower ends of the fourth lower electrodes BE4 may be disposed to penetrate portions of the second pad BP2. The fourth lower electrodes BE4 may be formed of a conductive material. For example, the fourth lower electrodes BE4 may be formed of impurity-doped poly silicon, or may be formed of a metal containing film such as a titanium nitride film. The fourth lower electrodes BE4 may have a pillar shape or a cylindrical shape.

A seventh support pattern SL7 and an eighth support pattern SL8 that extend in the first direction D1 may be between the fourth lower electrodes BE4. The eighth support pattern SL8 may support upper sidewalls of the fourth lower electrodes BE4, and the seventh support pattern SL7 may support lower sidewalls of the fourth lower electrodes BE4. The seventh support pattern SL7 and the eighth support pattern SL8 may include, e.g., a material such as silicon nitride, silicon oxide, or silicon oxy-nitride.

The fourth dielectric film DL4 may cover surfaces of the fourth lower electrodes BE4 and surfaces of the seventh and eighth support patterns SL7 and SL8. The fourth dielectric film DL4 may include, e.g., silicon oxide, silicon nitride, silicon oxy-nitride, or a high-k material. The fourth upper electrode UE4 may be on the fourth dielectric film DL4 and may fill spaces between the fourth lower electrodes BE4. The fourth upper electrode UE4 may include, e.g., an impurity-doped poly silicon film, metal nitride such as titanium nitride, or a metal film such as tungsten, aluminum, or copper. The fourth capacitor CA4 may vertically overlap at least some of the first transistors TR1.

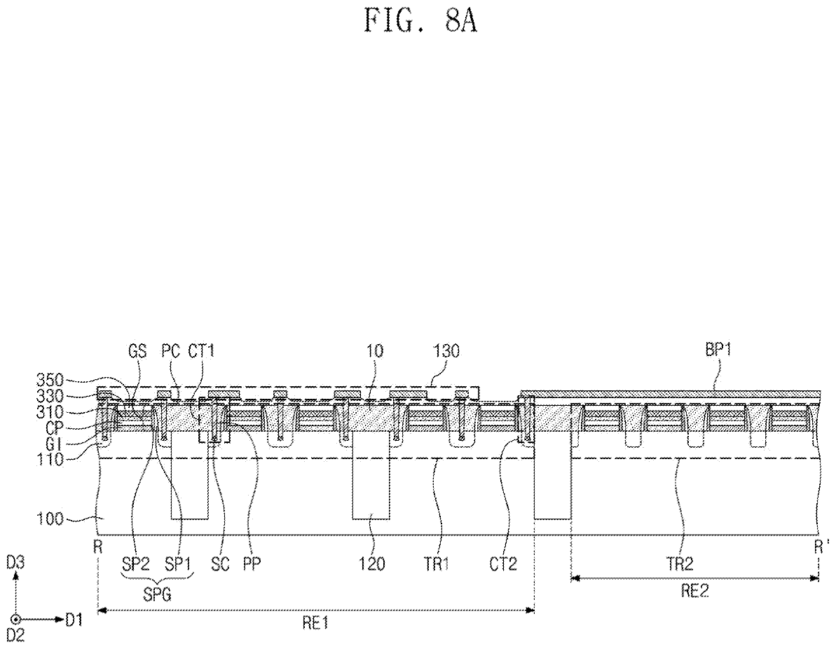

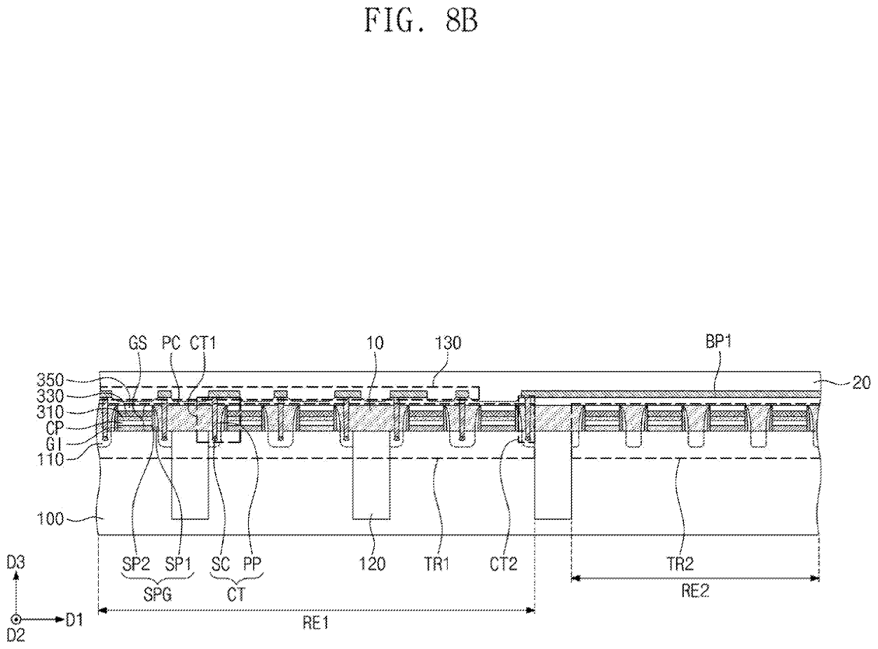

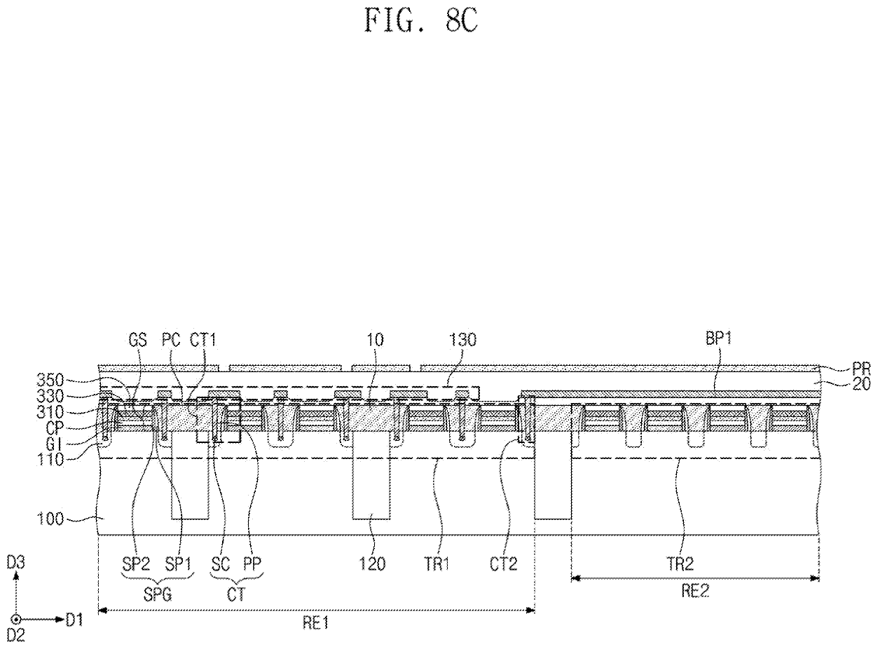

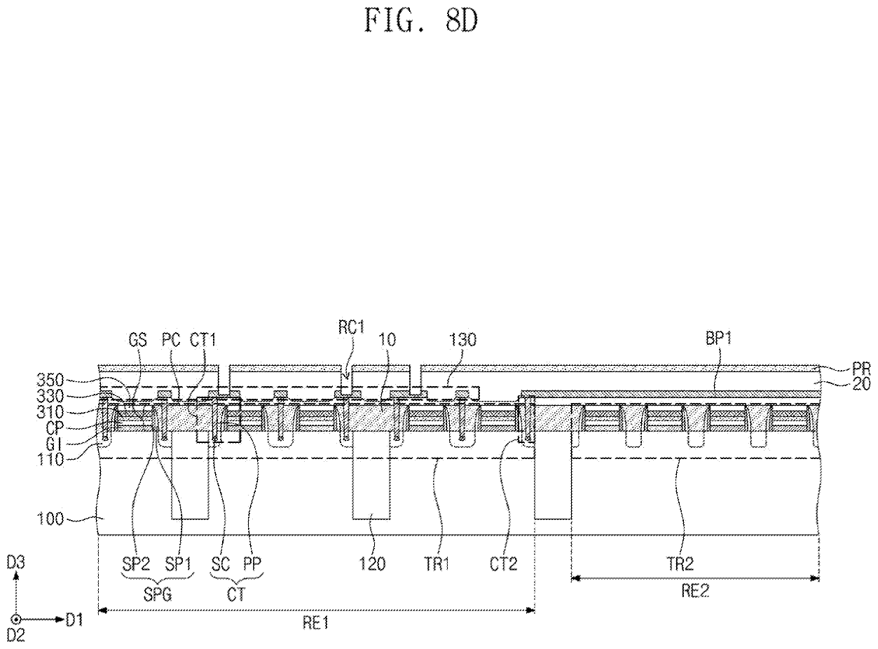

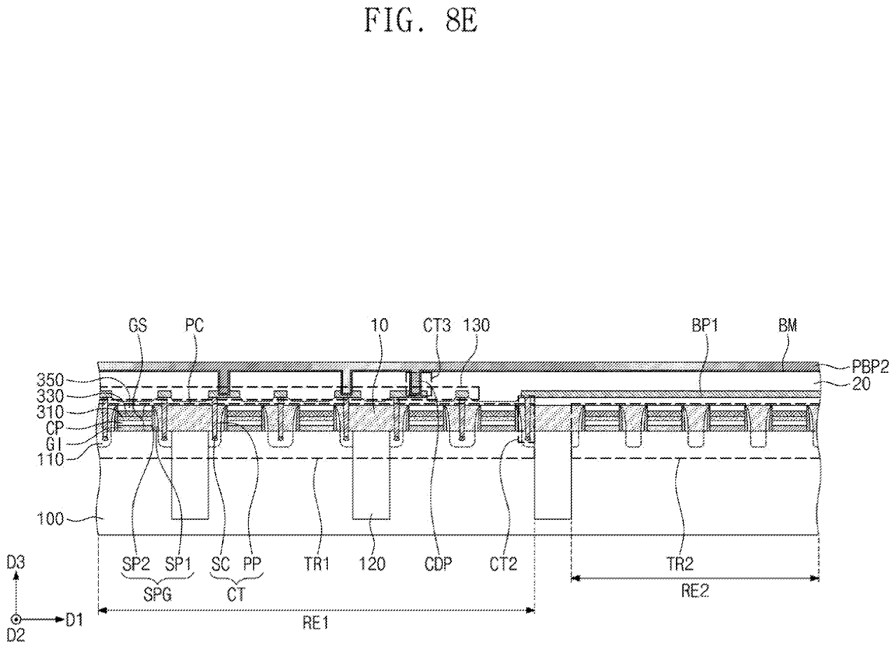

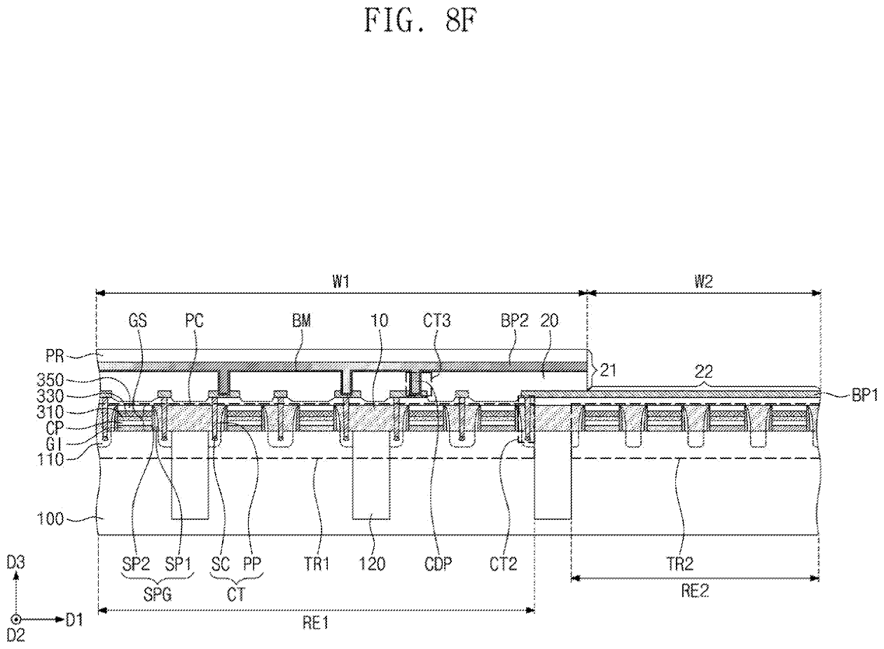

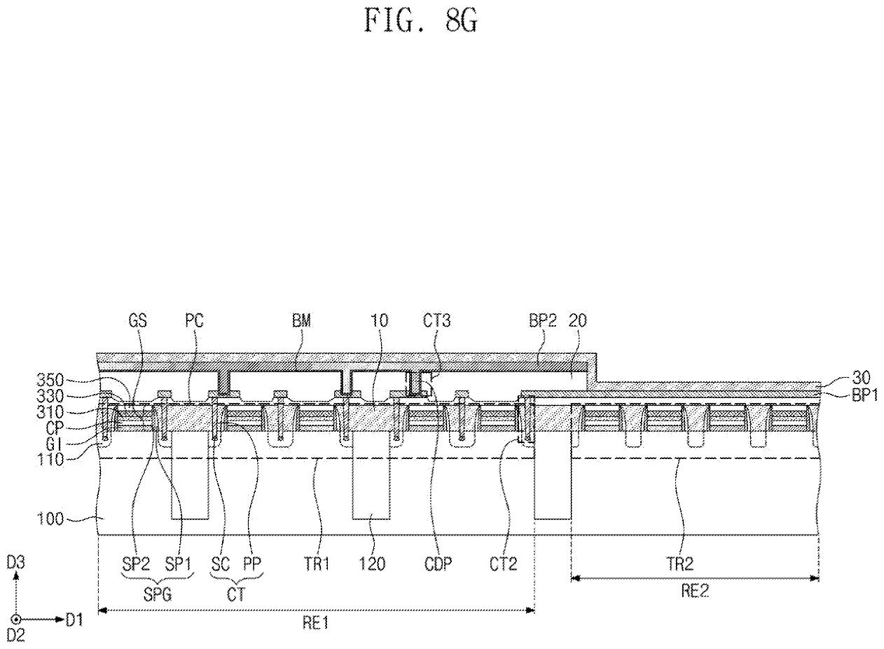

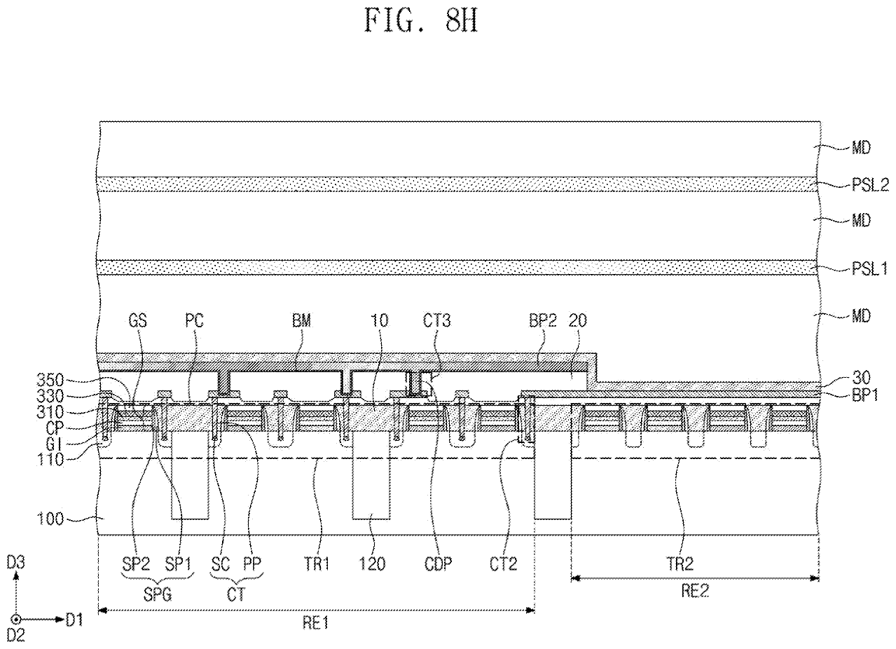

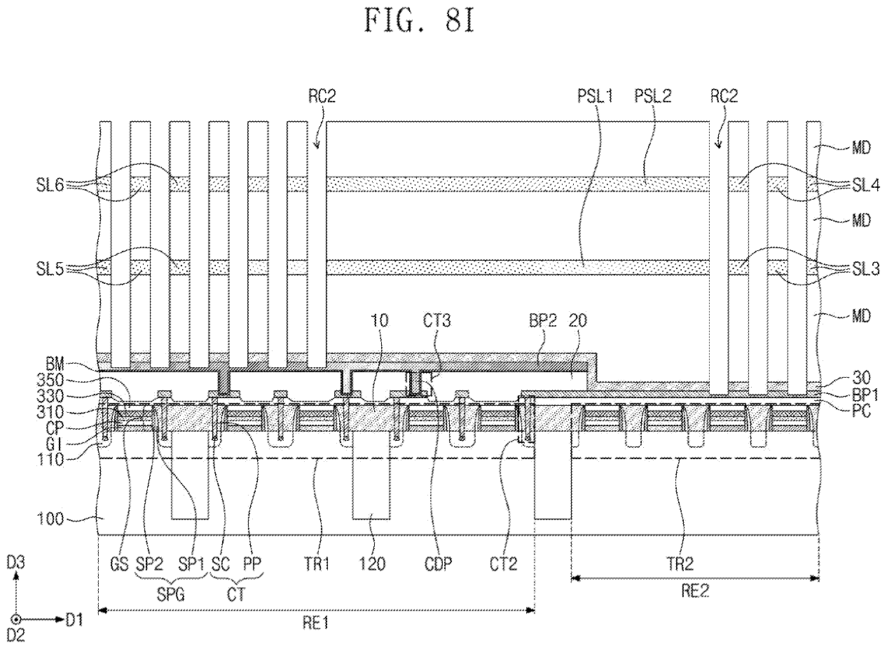

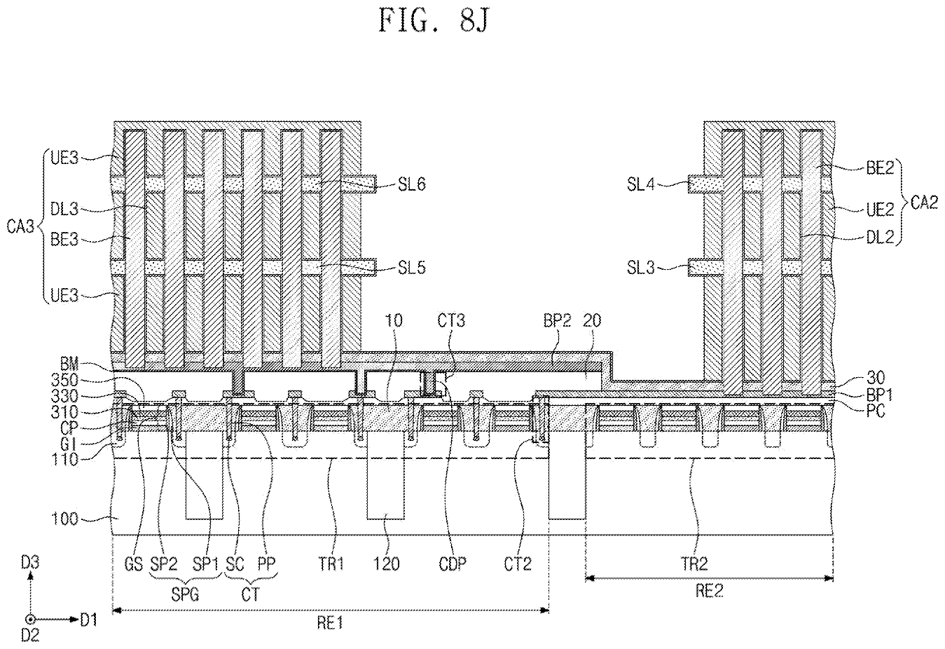

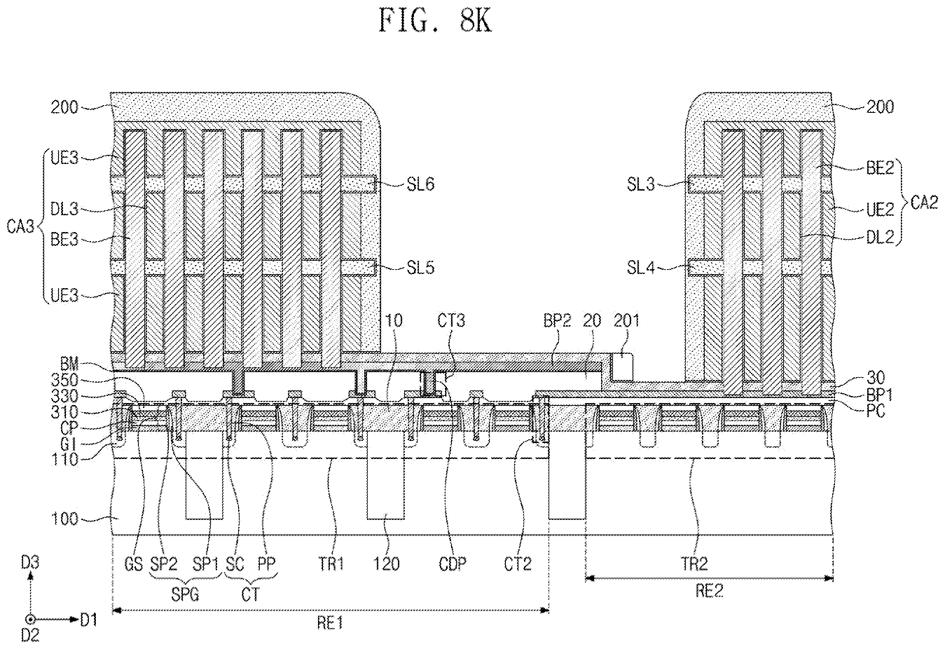

FIGS. 8A to 8K are sectional views of a semiconductor device showing various steps in a method of manufacturing the semiconductor device according to an embodiment of the present disclosure.

Referring to FIG. 8A, the semiconductor substrate 100 may include the first area RE1 and the second area RE2 may be provided. The device isolation film 120 may be formed on the semiconductor substrate 100. The device isolation film 120 may be formed through a device isolation process such as a shallow trench isolation (STI) process.

The first transistors TR1, which include the gate structure GS and the impurity area 110, may be formed on the first area RE1 of the semiconductor substrate 100. The impurity area 110 may be formed through an ion implantation process. Likewise, the second transistors TR2, which include the gate structure GS and the impurity area 110, may be formed on the second area RE2 of the semiconductor substrate 100.

Subsequently, the third interlayer insulating film 10 and the peripheral capping pattern PC on the third interlayer insulating film 10 may be formed. The contact pad SC may be embedded in an empty space formed by etching the third interlayer insulating film 10 and the peripheral capping pattern PC. The first contact plug CT1 and the second contact plug CT2 may be formed by connecting the through-plug PP to the contact pad SC. The first wiring layer 130 connected with the first contact plug CT1 may be formed. In addition, the first pad BP1 connected with the second contact plug CT2 may be formed. The first pad BP1 may be in a plate shape that covers the second transistors TR2.

Referring to FIG. 8B, the fourth interlayer insulating film 20 may be formed on the peripheral capping pattern PC, the first wiring layer 130, and the first pad BP1.

Referring to FIG. 8C, a mask pattern PR may be formed on the fourth interlayer insulating film 20. The mask pattern 620 may include forming, exposing, and developing a photoresist layer.

Referring to FIG. 8D, the fourth interlayer insulating film 20 may be etched using the mask pattern PR as an etching mask. A first recess portion RC1 may be formed through an etching process. The etching process may be an anisotropic etching process, and the mask pattern PR may be removed after or during the etching process. The first recess portion RC1 may be formed by the etching process. A plurality of first recess portions RC1 may be formed. The etching process may be performed using an etch selectivity until an upper surface of the first wiring layer 130 is exposed.

Referring to FIG. 8E, the third contact plug CT3 may be formed on the first wiring layer 130. The third contact plug CT3 may include the conductive plug CDP and the barrier metal BM. The barrier metal BM may be formed along the shape of a side surface and a lower end surface of the first recess portion RC1. The barrier metal BM may extend from the side surface of the first recess portion RC1 and may extend on the first area RE1 and the second area RE2 in the first direction D1. The conductive plug CDP may be formed by filling the inside of the first recess portion RC1. The conductive plug CDP may be formed through a chemical vapor deposition process. When the chemical vapor deposition process is used, the inside of the first recess portion RC1 may be formed as the conductive plug CDP without a blank space.

Subsequently, a preliminary second pad PBP2 may be formed on the third contact plug CT3. The preliminary second pad PBP2 may include the same material as the conductive plug CDP. A lower surface of the preliminary second pad PBP2 may be in contact with an upper surface of the conductive plug CDP. The preliminary second pad PBP2 may be formed on the first area RE1 and the second area RE2 in the first direction D1.

Referring to FIG. 8F, in an implementation, a mask pattern PR may be formed on the preliminary second pad PBP2. An etching process may be performed on the mask pattern PR, the preliminary second pad PBP2, and the fourth interlayer insulating film 20 by using the mask pattern PR as an etching mask until an upper surface 22 of the first pad BP1 on the second area RE2 is exposed. As the etching process is performed, the exposed upper surface 22 of the first pad BP1 may have a second width W2 parallel to the first direction D1.

In contrast, the mask pattern PR on the first area RE1 that exists after the etching may have a first width W1 parallel to the first direction D1. The first width W1 may be equal to the width of the first area RE1. Furthermore, as the etching process is performed, the preliminary second pad PBP2 on the second area RE2 may be removed, and the second pad BP2 may be subjected to patterning. The mask pattern PR on the first area RE1 may be removed during or after the etching process. Accordingly, the fourth interlayer insulating film 20, the barrier metal BM, and a side surface 21 of the second pad BP2 may be exposed.

Referring to FIG. 8G, the fifth interlayer insulating film 30 may be formed on the first pad BP1 and the second pad BP2. The fifth interlayer insulating film 30 may be formed in a shape that covers the fourth interlayer insulating film 20, the barrier metal BM, and the side surface 21 of the second pad BP2. The fifth interlayer insulating film 30 may include an insulating material. The insulating material may include, e.g., silicon nitride or silicon oxide.

Referring to FIG. 8H, the mold film MD and a first support layer PSL1 and a second support layer PSL2 inside the mold film MD may be formed on the fifth interlayer insulating film 30. The first support layer PSL1 and the second support layer PSL2 may be formed in a shape extending in the first direction D1. The first support layer PSL1 and the second support layer PSL2 may be spaced apart from each other in the third direction D3. The first support layer PSL1 may be formed closer to the upper surface of the semiconductor substrate 100 than the second support layer PSL2.

Referring to FIG. 8I, in an implementation, an etching process may be performed on the mold film MD, the first support layer PSL1, and the second support layer PSL2 by using a mask pattern. A plurality of second recess portions RC2 may be formed through the etching process.

An etching process performed on the first area RE1 may be performed in the third direction D3 to an inner area of the second pad BP2 through the fifth interlayer insulating film 30 and the upper surface of the second pad BP2. However, the etching process performed on the first area RE1 is not performed to a depth by which the upper surface of the barrier metal BM is exposed.

An etching process performed on the second area RE2 may be performed in the third direction D3 to an inner area of the first pad BP1 through the fifth interlayer insulating film 30 and the upper surface of the first pad BP1. However, the etching process performed on the second area RE2 is not performed to a depth by which the lower surface of the first pad BP1 is exposed.

As the etching process is performed, the first support layer PSL1 and the second support layer PSL2 may be subjected to patterning, and the third support pattern SL3, the fourth support pattern SL4, the fifth support pattern SL5, and the sixth support pattern SL6 may be formed. Meanwhile, the mold film MD, the first support layer PSL1, and the second support layer PSL2 that are not etched may exist on a portion of the first area RE1 and the upper surface of the second area RE2.

Referring to FIG. 8J, the second capacitor CA2 and the third capacitor CA3 may be formed on the first pad BP1 and the second pad BP2, respectively.

In the case of the second capacitor CA2, the second lower electrodes BE2 may be formed by filling the second recess portions RC2 on the second area RE2 with a conductive material. The second lower electrodes BE2 may be deposited in the third direction D3 by a deposition process such as a physical vapor deposition process, a chemical vapor deposition process, or an atomic layer deposition process. The second dielectric film DL2 may be formed to cover the upper surfaces and the sidewalls of the second lower electrodes BE2 and the upper and lower surfaces and the side surfaces of the third and fourth support patterns SL3 and SL4 on the second area RE2. The second dielectric film DL2 may be formed using chemical vapor deposition and atomic layer deposition. Subsequently, the second upper electrode UE2 may be formed on the second dielectric film DL2. That is, the second upper electrode UE2 may be formed on the second dielectric film DL2 to fill the spaces between the second lower electrodes BE2. The second upper electrode UE2 may be formed by the same deposition process as the deposition process of the second lower electrodes BE2. In an implementation, a heat treatment process may be further included after the formation of the second upper electrode UE2. The second upper electrode UE2, the second lower electrodes BE2, and the second dielectric film DL2 may be additionally crystallized through the heat treatment process.

Meanwhile, the third capacitor CA3 may be formed on the second pad BP2. The third lower electrodes BE3 may be formed by filling the second recess portions RC2 on the first area RE1 with a conductive material. The third dielectric film DL3 may be formed to cover the upper surfaces and the sidewalls of the third lower electrodes BE3 and the upper and lower surfaces and the side surfaces of the fifth and sixth support patterns SL5 and SL6 on the first area RE1. The third dielectric film DL3 may be formed by the same deposition process as the deposition process of the second dielectric film DL2. Subsequently, the third upper electrode UE3 may be formed on the third dielectric film DL3. That is, the third upper electrode UE3 may be formed on the third dielectric film DL3 to fill the spaces between the third lower electrodes BE3. The third lower electrodes BE3 and the third upper electrode UE3 may be formed by the same deposition process as the deposition process of the second lower electrodes BE2 and the second upper electrode UE2. The unetched mold film MD, the unetched first support layer PSL1, and the unetched second support layer PSL2 on the upper surface of the semiconductor substrate 100 may be removed.

Referring to FIG. 8K, the plates 200 may be formed on the second capacitor CA2 and the third capacitor CA3, respectively. The plate 200 on the first area RE1 may be formed in a shape that covers the third capacitor CA3. The plate 200 on the second area RE2 may be formed in a shape that covers the second capacitor CA2. The plates 200 may be formed through a chemical vapor deposition process.

Meanwhile, due to the chemical vapor deposition process, the residual plate 201 may be formed on the fifth interlayer insulating film 30. The residual plate 201 may be formed on the second area RE2.

Referring again to FIG. 5A, the mold film MD may be formed on the fifth interlayer insulating film 30, the plates 200, and the residual plate 201. Thereafter, in an implementation, in empty spaces formed by etching the mold film MD, the metal plugs MP may be formed on the first pad BP1 and the second pad BP2 in the third direction D3. A part of the metal plugs MP may be formed to be connected with the plate 200. Meanwhile, the wiring layer 40 may be formed on the metal plugs MP, and the metal pattern 300 may be included in the wiring layer 40. The upper ends of the metal plugs MP may be formed to be connected with the metal pattern 300.

The semiconductor device according to the present disclosure may include the first pad, the capacitor connected with the first pad, the second pad vertically spaced apart from the first pad, and the capacitor connected with the second pad. As the structure according to the present disclosure is used, several operating circuits may be provided at the lower end of the second pad, and thus space utilization efficiency may be increased. In addition, as the capacitors are perpendicular to the first and second pads, the size of the semiconductor device may be reduced.

By way of summation and review, embodiments of the present disclosure provide a semiconductor device having improved reliability and electrical characteristics.

While the present disclosure has been described with reference to embodiments thereof, it will be apparent to those of ordinary skill in the art that various changes and modifications may be made thereto without departing from the spirit and scope of the present disclosure as set forth in the following claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a semiconductor substrate including a cell area and a peripheral area, the peripheral area including a first area and a second area adjacent to each other;
first transistors on the first area;
a first wiring layer on the first transistors;
a first pad on the second area and on a portion of the first area;
a first contact plug between the first wiring layer and the first area;
a second contact plug between the first pad and the first area;
a second pad on the first wiring layer,
a third contact plug between the second pad and the first wiring layer; and
a plurality of first capacitors on the second pad vertically overlapping the first transistors.

2. The semiconductor device as claimed in claim 1, further comprising dummy transistors on the second area.

3. The semiconductor device as claimed in claim 2, wherein:
the first pad vertically overlaps the dummy transistors, and
the second pad vertically overlaps the first capacitors.

4. The semiconductor device as claimed in claim 1, further comprising a device isolation film on the semiconductor substrate spacing apart the first area and the second area.

5. The semiconductor device as claimed in claim 1, wherein the second pad is on the first area and on a portion of the second area.

6. The semiconductor device as claimed in claim 1, further comprising plates on the first capacitors and a residual plate on the second area.

7. The semiconductor device as claimed in claim 1, wherein:
the third contact plug includes a conductive plug and a barrier metal, and
the barrier metal covers a side surface and a lower surface of the conductive plug.

8. The semiconductor device as claimed in claim 7, wherein the barrier metal extends from the side surface of the conductive plug and is on a lower surface of the second pad.

9. The semiconductor device as claimed in claim 8, wherein the conductive plug includes a material different from a material of the second pad.

10. The semiconductor device as claimed in claim 1, wherein the first pad and the second pad are spaced apart from each other in a third direction perpendicular to an upper surface of the semiconductor substrate.

11. A semiconductor device, comprising:
a semiconductor substrate including a cell area and a peripheral area, the peripheral area including a first area and a second area adjacent to each other;
first transistors on the first area;
a first wiring layer on the first transistors;
a first pad on the second area;
a second pad on the first wiring layer and on the first area spaced apart from the first pad in a third direction perpendicular to an upper surface of the semiconductor substrate;
a first contact plug configured to connect the first wiring layer and the second pad;
a first capacitor on the second pad including a first lower electrode connected with the second pad, a first upper electrode on the lower electrode, and a first dielectric film between the first lower electrode and the first upper electrode; and
a second capacitor on the first pad including a second lower electrode connected with the first pad, a second upper electrode on the second lower electrode, and a second dielectric film between the second lower electrode and the second upper electrode.

12. The semiconductor device as claimed in claim 11, further comprising a dummy transistor on the second area.

13. The semiconductor device as claimed in claim 11, wherein a level difference between a lower surface and an upper surface of the first lower electrode differs from a level difference between a lower surface and an upper surface of the second lower electrode.

14. The semiconductor device as claimed in claim 11, wherein the first pad extends to a portion of the first area beyond the second area, and the second pad extends to a portion of the second area beyond the first area.

15. The semiconductor device as claimed in claim 11, wherein a level of a lower surface of the first lower electrode is higher than a level of a lower surface the second lower electrode.

16. The semiconductor device as claimed in claim 11, further comprising:
a first metal plug on the first pad and spaced apart from the second capacitor; and
a second metal plug on the second pad and spaced apart from the first capacitor.

17. A semiconductor device, comprising:
a semiconductor substrate including a cell area and a peripheral area around the cell area, the peripheral area including a first area and a second area;
cell activation patterns on the cell area;
word lines configured to cross the cell activation patterns inside the semiconductor substrate;
bit lines configured to cross the word lines on the semiconductor substrate;
a landing pad on the bit lines;
a first capacitor on the landing pad;
second transistors on the second area;
a first pad electrically connected with the bit lines and on the second area, a portion of the first area, and the second transistors;
first transistors on the first area;
a first wiring layer on the first transistors;
a second pad on the first wiring layer, the first area, and a portion of the second area spaced apart from the first pad in a third direction perpendicular to an upper surface of the semiconductor substrate;
a third contact plug configured to connect the first wiring layer and the second pad;
a second capacitor on the second pad; and
a third capacitor on the first pad.

18. The semiconductor device as claimed in claim 17, further comprising a via configured to connect the bit lines and the first pad.

19. The semiconductor device as claimed in claim 17, wherein the landing pad and an upper surface of the first pad are at the same level.

20. The semiconductor device as claimed in claim 17, wherein the second capacitor and the third capacitor are spaced apart from each other in a first direction.
